(19) United States
(12) Patent Application Publication
(10) Pub. No.: US 2012/0155200 A1
(43) Pub. Date: Jun. 21, 2012

(54) MEMORY DEVICE, MEMORY SYSTEM INCLUDING THE SAME, AND CONTROL METHOD THEREOF

(76) Inventors: Young-Suk Moon, Gyeonggi-do (KR); Hyung-Dong Lee, Gyeonggi-do (KR); Jeong-Woo Lee, Gyeonggi-do (KR); Sang-Hoon Shin, Gyeonggi-do (KR)

(21) Appl. No.: 13/299,497

(22) Filed: Nov. 18, 2011

(30) Foreign Application Priority Data
Dec. 16, 2010 (KR) 10-2010-0128942

(51) Int. Cl. G11C 8/18; G11C 7/12; G11C 8/00

(52) U.S. Cl. 365/193; 365/230.01; 365/230.03; 365/203

(57) ABSTRACT

A memory system includes a memory device, a control device configured to control the memory device, a first channel configured to transfer a row command from the control device to the memory device, and a second channel configured to transfer a column command from the control device to the memory device.

### CROSS-REFERENCE TO RELATED APPLICATIONS

The present application claims priority of Korean Patent Application No. 10-2010-0128942, filed on Dec. 16, 2010, which is incorporated herein by reference in its entirety.

### BACKGROUND OF THE INVENTION

Exemplary embodiments of the present invention relate to a memory device, a memory system including the memory device, and a method for controlling the memory device.

As well known, a memory device includes a memory cell region, which may have a plurality of banks and peripheral circuits for controlling data input/output to/from the memory cell region. A bank is an aggregate of memory cells each capable of storing a data. Also, memory cells are arrayed between a plurality of rows and a plurality of columns to form a cell array. Each of the rows and columns is assigned an address.

A data access operation in one bank of a memory device includes amplifying word lines corresponding to an applied row address into an active state, inputting or outputting a data to or from a memory cell of a bit line corresponding to an applied column address among the activated word lines, and pre-charging the word lines. As described above, the operation of the memory cell region is divided into an operation of controlling word lines and an operation of controlling bit lines. Herein, the former operation is referred to as a row operation and the latter operation is referred to as a column operation. Also, a command applied for the row operation is referred to as a row command, and a command applied for the column operation is referred to as a column command.

FIG. 1 is a block view illustrating a known memory device.

Referring to FIG. 1, the known memory device includes a command decoder 101, an address storage 103, a bank selector 105, and a memory cell region 107. As shown in FIG. 1, the memory cell region 107 may include 8 banks, which are referred to herein as first to eighth banks BANK0 to BANK7.

The command decoder 101 operates when a chip selection signal /CS is in a logic low level. More specifically, the command decoder 101 receives a row address strobe signal /RAS, a column address signal /CAS, and a write enable signal /WE, decodes these received signals, and generates an internal command ICMD. The internal command ICMD may be output on a plurality of lines and may represent any one of a number of different commands, such as an active command, a read command, a write command, etc.

The address storage 103 inputs an address ADD that corresponds to the internal command ICMD. Further, the address storage 103 buffers the address ADD, and transfers a bank address BADD to the bank selector 105 and a row address RADD and a column address CADD to all the banks BANK0 to BANK7 of the memory cell region 107.

The bank selector 105 transfers the internal command ICMD generated in the command decoder 101 to a bank corresponding to the received bank address BADD. To accomplish this task, respective lines are provided from the bank selector 105 to the first to eighth banks BANK0 to BANK7 in the memory cell region 107.

Therefore, the first to eighth banks BANK0 to BANK7 respectively receive first to eighth internal commands ICMD_B<0:7> of which one of the commands is the internal command ICMD. In other words, the internal command ICMD is transferred as one of the first to eighth internal commands ICMD_B<0:7> so that the internal command ICMD is provided to the appropriate bank, designated by the bank address BADD, among the banks BANK0 to BANK7. Accordingly, a row operation and a column operation based on the row address RADD and the column address CADD may be performed on the appropriate bank.

FIG. 2 shows a series of exemplary commands applied at clock cycles during an operation of the memory device of FIG. 1.

Referring to FIG. 2, a write operation and a read operation are sequentially performed five times for each of the eight (8) banks BANK0 to BANK7 of the memory cell region 107. In the drawing, reference symbols ‘A0 to A7’ denote row commands for activating particular word lines in the first to eighth banks BANK0 to BANK7, respectively. Meanwhile, reference symbols ‘P0 to P7’ denote row commands for pre-charging activated word lines in the first to eighth banks BANK0 to BANK7, respectively. Further, reference symbols ‘W0 to W7’ denote column commands for inputting data through particular bit lines in the first to eighth banks BANK0 to BANK7, respectively. That is, ‘W0 to W7’ represent column commands for performing a write operation. For example, W0 represents a column command for performing a write operation in corresponding BANK0. Also, because the write operation is performed five times for each bank, there are five W0s, five W1s, five W2s, etc. Lastly, reference symbols ‘R0 to R7’ denote column commands for outputting data through particular bit lines in the first to eighth banks BANK0 to BANK7, respectively. That is, ‘R0 to R7’ represent column commands for performing a read operation. For example, R0 represents a column command for performing a read operation in corresponding BANK0. Also, because the read operation is performed five times for each bank, there are five R0s, five R1s, five R2s, etc.

FIG. 2 shows exemplary commands for the memory device of FIG. 1 given the following basic specifications.

tRAS (which is a minimum time required between a moment of activating one bank and a moment of pre-charging said bank)=15 clock cycles (tCLK)

tRP (which is a minimum time required between a moment of pre-charging one bank and a moment of re-activating said bank)=7 clock cycles (tCLK)

tRRD (which is a minimum time required between a moment of activating one bank and a moment of activating another bank, i.e., a RAS to RAS delay)=5 clock cycles (tCLK)

tRCDW (which is a minimum time required between a moment of activating one bank and a moment of writing data into said bank, i.e., a RAS to CAS delay during a write operation)=5 clock cycles (tCLK)

tRCDR (which is a minimum time required between a moment of activating one bank and a moment of reading data from said bank, i.e., a RAS to CAS delay during a read operation)=8 clock cycles (tCLK)

tFAW (which is a minimum window of time required for activating four different banks, i.e., the four activate window delay)=25 clock cycles (tCLK)

Referring to FIG. 2, an A0 command is applied in the first clock cycle to activate a first bank BANK0 for a write operation. Because tRRD=5 and tRCDW=5, an A1 command and a W0 command may be simultaneously applied in the sixth clock cycle. However, because the commands are applied through a single command channel, the A1 command is applied first and then the W0 command is applied in the next clock cycle. Likewise, in the 11^{th} clock, a W0 command is pushed back one clock cycle to make room for an A2 command being applied. In the known memory device, the phenomenon that a column command is pushed back one clock cycle at a moment when a row command is applied occurs.

In other words, since a row command and a column command are applied to the command decoder 101 through the same channel in the known memory device shown in FIG. 1, the row command and the column command for different banks cannot be simultaneously applied. Instead, row commands and column commands are delayed and applied sequentially although they are commands for different banks. Therefore, it is not possible to perform a row operation and a column operation simultaneously in different banks. For this reason, the bandwidth for input/output data is restructured according to predetermined priority levels. In sum, when there are many banks in the known memory device, the system operation becomes complicated and the data processing rate decreases.

### SUMMARY OF THE INVENTION

Exemplary embodiments of the present invention are directed to a memory device that may increase the bandwidth for input/output data and alleviate system complexity in terms of a processor, a memory system including the memory device, and a method for controlling the memory device.

In accordance with an exemplary embodiment of the present invention, a memory system includes a memory device, a control device configured to control the memory device, a first channel configured to transfer a row command from the control device to the memory device, and a second channel configured to transfer a column command from the control device to the memory device.

The control device may simultaneously transfer the row command and the column command through the first channel and the second channel respectively.

The control device may further transfer a first operation signal to the memory device through the first channel when the control device transfers the row command, and the control device may further transfer a second operation signal to the memory device through the second channel when the control device transfers the column command.

In accordance with another exemplary embodiment of the present invention, a memory device includes a memory cell region comprising a plurality of banks, a row command decoder configured to generate an internal row command by decoding a row command transferred through a first channel, a first address storage configured to receive a first bank address and a row address, which correspond to the row command, through the first channel, a first bank selector configured to transfer the internal row command to a first bank among the plurality of banks corresponding to the first bank address, a column command decoder configured to generate an internal column command by decoding a column command transferred through a second channel, a second address storage configured to receive a second bank address and a column address, which correspond to the column command, through the second channel, and a second bank selector configured to transfer the internal column command to a second bank among the plurality of banks corresponding to the second bank address.

The row command and the column command may be simultaneously transferred to the memory device through the first channel and the second channel, respectively. When the row command and the column command are simultaneously transferred, the first bank address and the second bank address may be different from each other.

A row operation based on the internal row command and a column operation based on the internal column command may be performed independently from each other.

In accordance with yet another exemplary embodiment of the present invention, a method for operating a memory system comprising a memory device includes transferring a first row command to a first bank of the memory device through a first channel, and transferring a first column command to the first bank through a second channel, wherein the first channel and the second channel are different channels.

The method may also include transferring a second row command to a second bank of the memory device through the first channel, and transferring a second column command to the second bank through the second channel. Further, the transferring of the first column command and the transferring of the second row command may be performed simultaneously.

In accordance with still another exemplary embodiment of the present invention, a method for operating a memory system comprising a memory device includes transferring a row command to a first bank of the memory device through a first channel, transferring a column command to a second bank of the memory device through a second channel, performing a row operation in the first bank in response to the row command, and performing a column operation in the second bank in response to the column command, wherein the row operation and the column operation are performed in the same clock cycle of the memory device.

### BRIEF DESCRIPTION OF THE DRAWINGS

FIG. 1 is a block view illustrating a known memory device.

FIG. 2 shows a series of exemplary commands applied at clock cycles to operate the memory device of FIG. 1.

FIG. 3 illustrates a memory system in accordance with an exemplary embodiment of the present invention.

FIG. 4 is a block view illustrating a memory device 303 shown in FIG. 3.

FIG. 5 is a block view illustrating a memory cell region 401 shown in FIG. 3.

FIGS. 6A to 6C are timing diagrams illustrating a chip selection signal used in a known memory device, and first and second operation signals used in exemplary embodiments of the present invention.

FIG. 7 shows exemplary commands applied at clock cycles during to operate a memory device in accordance with an exemplary embodiment of the present invention.

FIG. 8 illustrates a rank system including a plurality of memory devices in accordance with an exemplary embodiment of the present invention.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

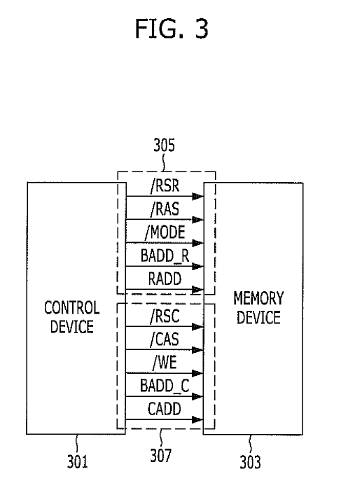

FIG. 3 illustrates a memory system in accordance with an exemplary embodiment of the present invention.

Referring to FIG. 3, the memory system includes a memory device 303, a control device 301 for controlling the memory device 303, a first channel 305 for applying a row command to the memory device 303, and a second channel 307 for applying a column command to the memory device 303.

The control device 301 applies a command and an address for a row operation through the first channel 305 and applies a command and an address for a column operation through the second channel 307. In short, different channels are used for transferring signals to the memory device 303 so that a row operation and a column operation may be performed independently.

To be specific, the control device 301 applies a first operation signal /RSR, a row address strobe signal /RAS, a mode signal /MODE, a first bank address BADD_R, and a row address RADD to the memory device 303 through the first channel 305, and applies a second operation signal /RSC, a column address strobe signal /CAS, a write enable signal /WE, a second bank address BADD_C, and a column address CADD to the memory device 303 through the second channel 307.

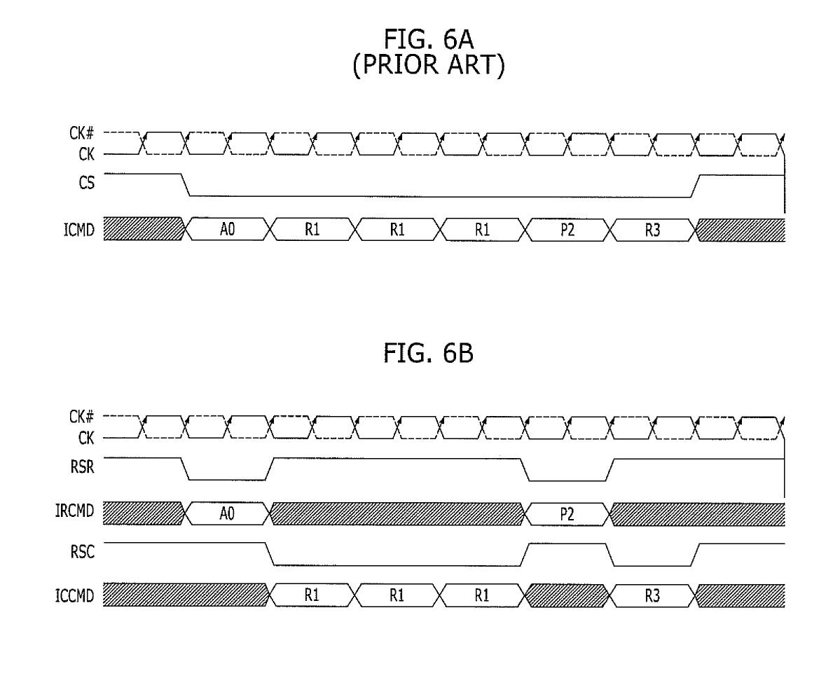

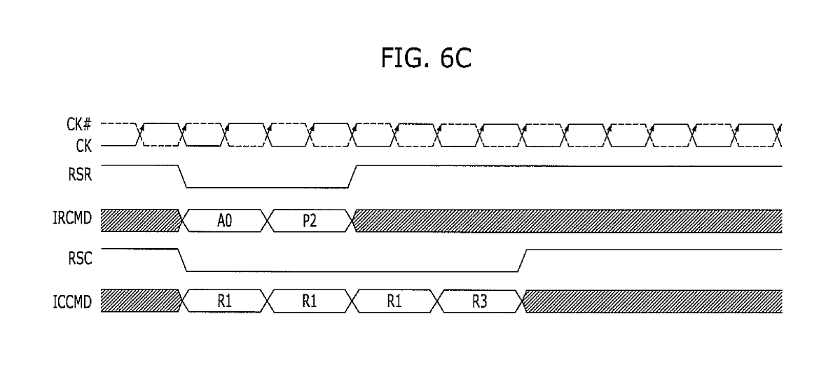

The first operation signal /RSR and the second operation signal /RSC are signals obtained from a chip selection signal /CS. In other words, the chip selection signal /CS, which enables both row and column operations in the known memory device, is separated into two different signals—the first operation signal /RSR for enabling a row operation and the second operation signal /RSC for enabling a column operation. Since the row operation and the column operation may be performed independently, when the first operation signal /RSR is enabled, structures for a row operation may be turned on in the memory device 303, and when the second operation signal /RSC is enabled, structures for a column operation may be turned on in the memory device 303. A further description of the first operation signal /RSR and the second operation signal /RSC is provided below with reference to FIGS. 6A to 6C.

The row command is a combination of the row address strobe signal /RAS and the mode signal /MODE, and the column command is a combination of the column address strobe signal /CAS and the write enable signal /WE. Table 1 is a table showing various operations of the memory device 303 based on combinations of signals outputted from the control device 301.

TABLE 1

| FUNCTION | /RSR | /RAS | /MODE | /RSC | /CAS | /WE |
|---|---|---|---|---|---|---|
| ROW NOP | L | H | H | X | X | X |
| ROW ACTIVE | L | L | H | X | X | X |
| ROW PRECHARGE | L | L | L | X | X | X |
| MODE REGISTER SET | L | H | L | X | X | X |
| COLUMN NOP | X | X | X | L | H | H |
| COLUMN READ | X | X | X | L | L | H |
| COLUMN WRITE | X | X | X | L | L | L |
| READ COUNTER | X | X | X | L | H | L |

When a row operation and a column operation are to be performed independently, addresses needed for the row operation and the column operation should be applied independently through different channels too. Therefore, the control device 301 may transfer the first bank address BADD_R and the row address RADD, which correspond to the row command, to the memory device 303 through the first channel 305, and may transfer the second bank address BADD_C and the column address CADD, which correspond to the column command, to the memory device 303 through the second channel 307.

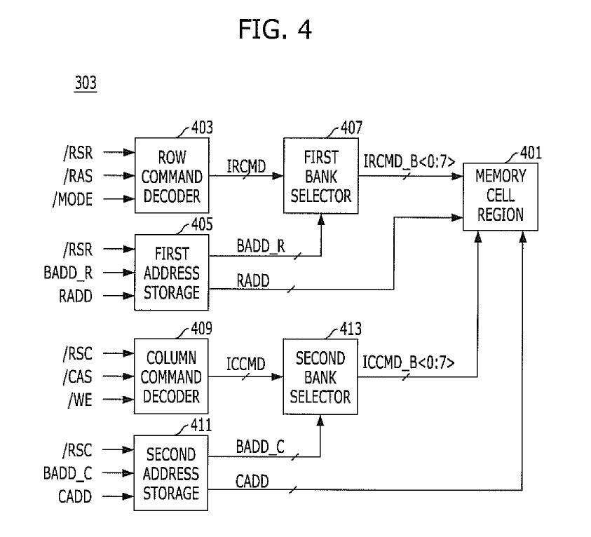

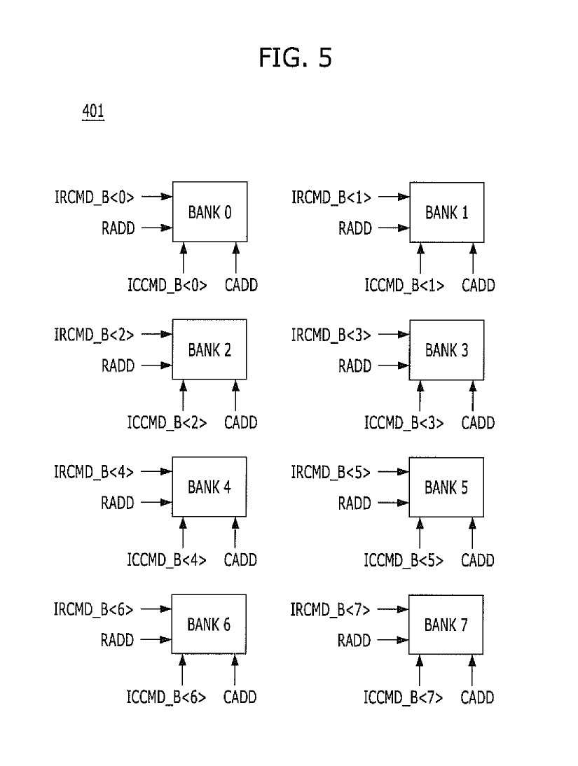

FIG. 4 is a block view illustrating the memory device 303 shown in FIG. 3. FIG. 5 is a block view illustrating a memory cell region 401 inside of the memory device 303 shown in FIG. 3.

Referring to FIG. 4, the memory device 303 includes a memory cell region 401 including a plurality of banks, a row command decoder 403, a first address storage 405, a first bank selector 407, a column command decoder 409, a second address storage 411, and a second bank selector 413. The row command decoder 403 receives the first operation signal /RSR, the row address strobe signal /RAS, and the mode signal /MODE, decodes these received signals, and generates an internal row command IRCMD. The internal row command IRCMD is a command for indicating a particular row operation to be performed in the memory cell region 401. Additionally, the first address storage 405 receives the first bank address BADD_R and the row address RADD, which correspond to the internal row command IRCMD, through the first channel 305. The first address storage 405 buffers the first bank address BADD_R and the row address RADD, and transfers the first bank address BADD_R to the first bank selector 407 and the row address RADD to the memory cell region 401. The first bank selector 407 transfers the internal row command IRCMD generated in the row command decoder 403 to a bank corresponding to the first bank address BADD_R. To accomplish this task, respective lines are provided from the first bank selector 407 to the banks in the memory cell region 401. For example, where the memory cell region 401 includes eight banks, eight lines are used to transfer first to eighth internal row commands IRCMD_B<0:7> from the first bank selector 407 to the memory cell region 401. Accordingly, the internal row command IRCMD can be transferred as one of the first to eighth internal row commands IRCMD_B<0:7> to the appropriate bank, designated by the first bank address BADD_R, among the eight banks of the memory cell region 401. The column command decoder 409 receives the second operation signal /RSC, the column address strobe signal /CAS, and the write enable signal /WE, decodes these received signals, and generates an internal column command ICCMD. The internal column command ICCMD is a command for indicating a particular column operation to be performed in the memory cell region 401. Additionally, the second address storage 411 receives the second bank address BADD_C and the column address CADD, which correspond to the internal column command ICCMD, through the second channel 307. The second address storage 411 buffers the second bank address BADD_C and the column address CADD, and transfers the second bank address BADD_C to the second bank selector 413 and the column address CADD to the memory cell region 401. The second bank selector 413 transfers the internal column command ICCMD generated in the column command decoder 409 to a bank corresponding to the second bank address BADD_C. To accomplish this task, respective lines are provided from the second bank selector 413 to the banks in the memory cell region 401. For example, where the memory cell region 401 includes eight banks, eight lines are used to transfer first to eighth internal column commands ICCMD_B<0:7> from the second bank selector 413 to the memory cell region 401. Accordingly, the internal column command ICCMD can be transferred as one of the first to eighth internal column commands ICCMD_B<0:7> to the appropriate bank, designated by the second bank address BADD_C, among the eight banks of the memory cell region 401.

Herein, it is assumed that the memory cell region 401 includes eight (8) banks, which are first to eighth banks BANK0 to BANK7.

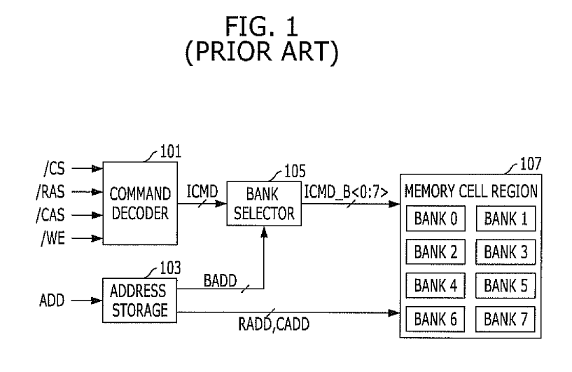

In case of the known memory device shown in FIG. 1, one command decoder 101 decodes both a row command and a column command. In contrast, according to the exemplary embodiment of the present invention, the memory device 303 has the row command decoder 403 and the column command decoder 409, and generates the row command and the column command independently from each other. In addition, the address storage 103 of the known memory device is also replaced with the first address storage 405 and the second address storage 411 in the memory device 303 according to an exemplary embodiment of the present invention. The first address storage 405 and the second address storage 411 in accordance with the present invention respectively latch the first bank address BADD_R and the row address RADD, which correspond to the row command, and the second bank address BADD_C and the column address CADD, which correspond to the column command, so that a row operation and a column operation can be performed independently from each other.

With regards to the row operation process, first, the first operation signal /RSR may be enabled to a logic low level to turn on the row command decoder 403 and the first address storage 405. Subsequently, the row address strobe signal /RAS and the mode signal /MODE are transferred to the row command decoder 403, while the first bank address BADD_R and the row address RADD, which correspond to the row command, are transferred to the first address storage 405.

Next, the row command decoder 403 decodes the row address strobe signal /RAS and the mode signal /MODE and generates an internal row command IRCMD. In other words, the row command decoder 403 determines an internal row command IRCMD based upon the row address strobe signal /RAS and the mode signal /MODE. The row command decoder 403 then transfers the generated internal row command IRCMD to the first bank selector 407. Meanwhile, the first address storage 405 transfers the first bank address BADD_R to the first bank selector 407 and the row address RADD to the memory cell region 401.

The first bank selector 407 transfers the internal row command IRCMD to a bank selected by the first bank address BADD_R. As a result, the first to eighth banks BANK0 to BANK7 inside of the memory cell region 401 respectively receive first to eighth internal row commands IRCMD_B<0> to IRCMD_B<7>corresponding thereto. Depending on the first to eighth internal row commands IRCMD_B<0:7>, one of the first to eighth banks BANK0 to BANK7 undergoes a row operation which activates or pre-charges a word line corresponding to the row address RADD transferred from the first address storage 405.

Similarly, the column operation corresponding to the column command is performed by the column command decoder 409, the second address storage 411, and the second bank selector 413 independently from the row operation.

First, the second operation signal /RSC may be enabled to a logic low level to turn on the column command decoder 409 and the second address storage 411. Subsequently, the column address strobe signal /CAS and the write enable signal /WE are transferred to the column command decoder 409, while the second bank address BADD_C and the column address CADD, which correspond to the column command, are transferred to the second address storage 411.

Next, the column command decoder 409 decodes the column address strobe signal /CAS and the write enable signal /WE and generates an internal column command ICCMD. In other words, the column command decoder 409 determines an internal column command ICCMD based upon the column address strobe signal /CAS and the write enable signal /WE. The column command decoder 409 then transfers the generated internal column command ICCMD to the second bank selector 413. Meanwhile, the second address storage 411 transfers the second bank address BADD_C to the second bank selector 413 and the column address CADD to the memory cell region 401.

The second bank selector 413 transfers the internal column command ICCMD to a bank selected by the second bank address BADD_C. As a result, the first to eighth banks BANK0 to BANK7 inside of the memory cell region 401 respectively receive first to eighth internal column commands ICCMD_B<0> to ICCMD_B<7>, corresponding thereto. Depending on the first to eighth internal column commands ICCMD_B<0:7>, one of the first to eighth banks BANK0 to BANK7 undergoes a column operation (e.g., reading or writing data) using a bit line corresponding to the column address CADD transferred from the second address storage 411.

In FIG. 5, the eight banks BANK0 to BANK7 included in the memory cell region 401 are shown in more detail. In particular, FIG. 5 shows that each bank receives a corresponding internal row command and a corresponding internal column command ICCMD. For example, the eighth bank BANK7 receives the eighth internal row command IRCMD_B<7> from among the first to eighth internal row commands IRCMD_B<0:7> through one line and receives the eighth internal column command ICCMD_B<7> from among the first to eighth internal column commands ICCMD_B<0:7> through another line.

As described above, it is possible to realize a system which may perform a row operation and a column operation simultaneously in different banks by separating the structure of the memory device 303 into a structure for a row operation and a structure for a column operation. In this way, data bandwidth of the memory device 303 may be increased, and therefore, a data processing rate of the system may be raised. Also, the system complexity in terms of a processor may be reduced.

Referring to FIGS. 6A to 6C, timing diagrams are provided to illustrate the results of separating the chip selection signal /CS (shown in its inverted form as CS) in the known memory device into the first operation signal /RSR (shown in its inverted form as RSR) and the second operation signal /RSC (shown in its inverted form as RSC). As described above, the first operation signal /RSR enables a row operation, while the second operation signal /RSC enables a column operation. FIG. 6A shows that the known memory device generates internal commands ICMD when the chip selection signal CS is activated to a low logic level. In particular, FIG. 6A shows that row commands (e.g., command A0 for activating a bank BANK0) and column commands (e.g., command R1 for reading data from a bank BANK1) are both transferred as the internal command ICMD, and therefore, are transferred through the same lines. In contrast, FIGS. 6B and 6C show that a memory device in accordance with an exemplary embodiment of the present invention generates the internal row command IRCMD when the first operation signal RSR is activated to a logic low level, and generates the internal column command ICCMD when the second operation signal RSC is activated to a logic low level. In the exemplary embodiment of FIG. 6B, the first operation signal RSR and the second operation signal RSC are not activated to a logic low level simultaneously. However, in another exemplary embodiment, as shown in FIG. 6C, the first operation signal RSR and the second operation signal RSC may be activated to a logic low level at the same time. Therefore, in the exemplary embodiment of FIG. 6C, the internal row command IRCMD may be provided to one bank at the same time that the internal column command ICCMD is provided to another bank. For example, referring to FIG. 6C, an activation command A0 may be provided to one bank BANK0, while a read command R1 is provided to another bank BANK1.

Herein, since a row command and a column command are received separately and addresses corresponding thereto are also received independently, the number of pins is increased. Therefore, the technology of the present invention may be usefully applied to a broadband input/output (IO) system in which the increase in the number of pins is acceptable, for example, in a system using a Through Silicon Via (TSV).

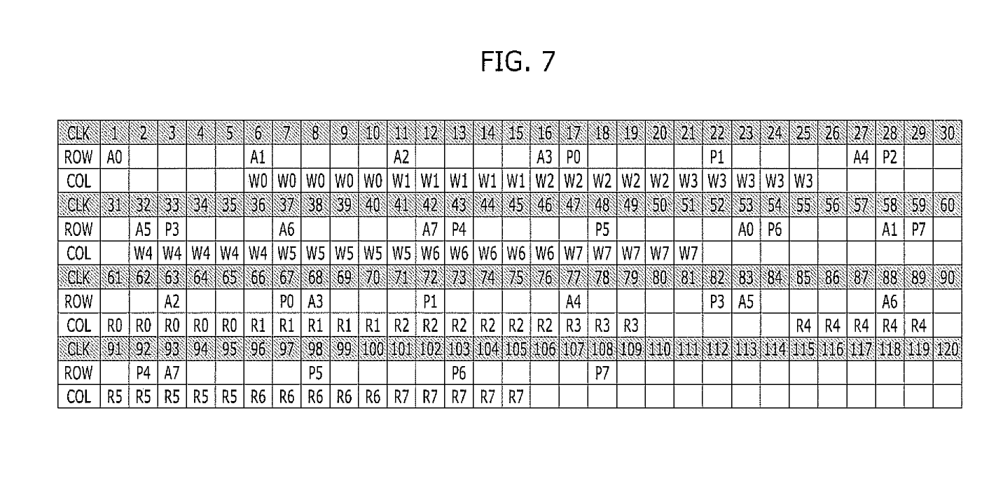

FIG. 7 shows exemplary commands applied at clock cycles during an operation of a memory device in accordance with an exemplary embodiment of the present invention.

Referring to FIG. 7, a write operation and a read operation are sequentially performed five times for each of the eight (8) banks BANK0 to BANK7 of the memory cell region 401. In the drawing, reference symbols ‘A0’ to ‘A7’ denote row commands for activating particular word lines in the banks BANK0 to BANK7, respectively.

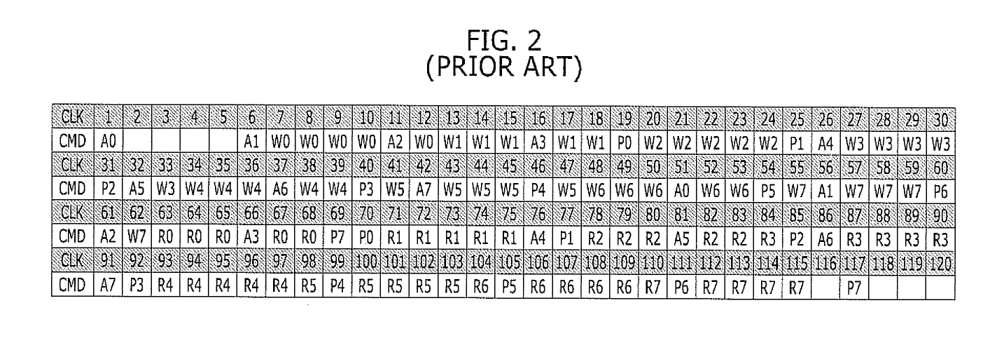

Meanwhile, reference symbols ‘P0’ to ‘P7’ denote row commands for pre-charging activated word lines in the banks BANK0 to BANK7, respectively. Further, reference symbols ‘W0’ to ‘W7’ denote column commands for inputting data through particular bit lines in the banks BANK0 to BANK7, respectively. That is, ‘W0 to W7’ represent column commands for performing a write operation for the banks BANK0 to BANK7, respectively. For example, W0 represents a column command for performing a write operation in corresponding BANK0. Also, because the write operation is performed five times for each bank, there are five W0s, five W1s, five W2s, etc. Lastly, reference symbols ‘R0’ to ‘R7’ denote column commands for outputting data through particular bit lines in the banks BANK0 to BANK7, respectively. That is, ‘R0 to R7’ represent column commands for performing a read operation. For example, R0 represents a column command for performing a read operation in corresponding BANK0. Also, because the read operation is performed five times for each bank, there are five R0s, five R1s, five R2s, etc. Herein, it is assumed, by way of example, that the specifications of the memory device used in FIG. 7 are the same as those described with reference to FIG. 2.

The difference between the known technology and exemplary embodiments of the present invention and the advantages of the exemplary embodiments of the present invention may become clear by comparing FIG. 7 with FIG. 2. As shown in FIG. 7, since a row command and a column command may be simultaneously applied to different banks through different channels, both a row operation and a column operation may be performed independently without interfering with each other. For example, in the sixth clock cycle (CLK 6), a row command A1 for activating one bank BANK1 may be applied at the same time as a column command W0 for writing data into another bank BANK0. Also, for example, in the seventy-second clock cycle (CLK 72), a row command P1 for pre-charging a word line in one bank BANK1 may be applied at the same time as a column command R2 for reading data from another bank BANK2.

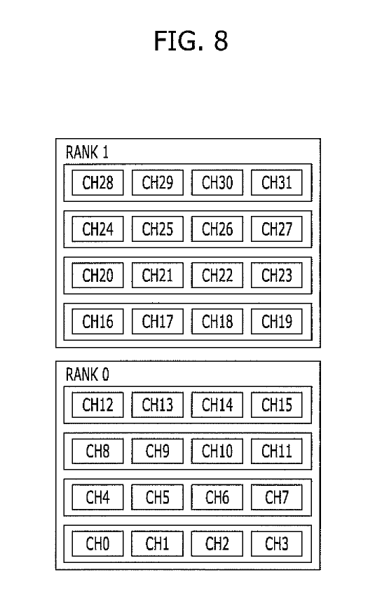

FIG. 8 illustrates a rank system including a plurality of memory devices in accordance with an exemplary embodiment of the present invention.

Referring to FIG. 8, a rank system includes a first rank RANK0 and a second rank RANK1, and the two ranks RANK0 and RANK1 may include sixteen (16) memory devices CH0 to CH15 and CH16 to CH31, respectively.

Memory devices at the same positions of the two ranks RANK0 and RANK1, for example, the memory devices at CH0 and CH16, share a command, an address, and a data channel. For this reason, in the known technology, the memory device at CH16 cannot perform any operation while the memory device at CH0 performs a row operation. In the rank system realized according to an exemplary embodiment of the present invention, however, the memory device at CH16 may perform a column operation while the memory device at CH0 performs a row operation. Therefore, a higher data bandwidth may be acquired while decreasing dependency between ranks.

According to an exemplary embodiment of the present invention, the data bandwidth of a memory device may be increased by applying a row command and a column command to a memory device through different channels.

Also, since a row operation and a column operation may be simultaneously performed in a plurality of banks independently from each other, the data processing rate of a system may be increased and/or system complexity in terms of a processor may be relieved.

Moreover, since a structure for performing the row operation and a structure for performing the column operation are separated, power consumption may be reduced by turning off the power of one structure when that structure is not used.

In addition, in a rank system linking a plurality of memory devices through a bus, dependency between ranks may be decreased and high data bandwidth may be acquired.

While the present invention has been described with respect to the specific embodiments, it will be apparent to those skilled in the art that various changes and modifications may be made without departing from the spirit and scope of the invention as defined in the following claims.

What is claimed is:

1. A memory system, comprising:
a memory device;
a control device configured to control the memory device;
a first channel configured to transfer a row command from the control device to the memory device; and
a second channel configured to transfer a column command from the control device to the memory device.

2. The memory system of claim 1, wherein the control device simultaneously transfers the row command and the column command through the first channel and the second channel respectively.

3. The memory system of claim 1, wherein the control device further transfers a first operation signal to the memory device through the first channel when the control device transfers the row command, and
the control device further transfers a second operation signal to the memory device through the second channel when the control device transfers the column command.

4. The memory system of claim 1, wherein the control device further transfers a first bank address and a row address which correspond to the row command to the memory device through the first channel, and
the control device further transfers a second bank address and a column address which correspond to the column command to the memory device through the second channel.

5. The memory system of claim 4, wherein when the row command and the column command are simultaneously applied to the memory device, the first bank address and the second bank address are different from each other.

6. The memory system of claim 1, wherein the row command comprises a row address strobe (RAS) signal and a mode signal.

7. The memory system of claim 1, wherein the column command comprises a column address strobe (CAS) signal and a write enable signal.

8. A memory device, comprising:
a memory cell region comprising a plurality of banks;
a row command decoder configured to generate an internal row command by decoding a row command transferred through a first channel;
a first address storage configured to receive a first bank address and a row address, which correspond to the row command, through the first channel;
a first bank selector configured to transfer the internal row command to a first bank among the plurality of banks corresponding to the first bank address;
a column command decoder configured to generate an internal column command by decoding a column command transferred through a second channel;
a second address storage configured to receive a second bank address and a column address, which correspond to the column command, through the second channel; and
a second bank selector configured to transfer the internal column command to a second bank among the plurality of banks corresponding to the second bank address.

9. The memory device of claim 8, wherein the row command and the column command are simultaneously transferred to the memory device through the first channel and the second channel, respectively.

10. The memory device of claim 9, wherein when the row command and the column command are simultaneously transferred, the first bank address and the second bank address are different from each other.

11. The memory device of claim 8, wherein a row operation based on the internal row command and a column operation based on the internal column command are performed independently from each other.

12. The memory device of claim 11, wherein the row operation comprises any operation that controls voltages of word lines of memory cells in the memory cell region and the column operation comprises any operation that controls voltages of bit lines of memory cells in the memory cell region.

13. The memory cell device of claim 12, wherein the row operation comprises an operation for activating particular word lines or pre-charging particular word lines.

14. The memory cell device of claim 12, wherein the column operation comprises inputting or outputting data through particular bit lines.

15. The memory device of claim 8, wherein the row command comprises a row address strobe (RAS) signal and a mode signal.

16. The memory device of claim 8, wherein the column command comprises a column address strobe (CAS) signal and a write enable signal.

17. The memory device of claim 8, wherein the first address storage transfers the row address to the memory cell region and the second address storage transfers the column address to the memory cell region.

18. A method for operating a memory system comprising a memory device, the method comprising:
transferring a first row command to a first bank of the memory device through a first channel; and
transferring a first column command to the first bank through a second channel,
wherein the first channel and the second channel are different channels.

19. The method of claim 18, further comprising:
transferring a second row command to a second bank of the memory device through the first channel; and
transferring a second column command to the second bank through the second channel.

20. The method of claim 19, wherein the transferring of the first column command and the transferring of the second row command are performed simultaneously.

21. The method of claim 18, further comprising:
transferring a bank address and a row address, which correspond to the first row command, to the memory device; and
transferring a bank address and a column address, which correspond to the first column command, to the memory device.

22. The method of claim 21, further comprising:
transferring a bank address and a row address, which correspond to the second row command, to the memory device through the first channel; and
transferring a bank address and a column address, which correspond to the second column command, to the memory device through the second channel.

23. The method of claim 22, wherein the bank addresses and the row addresses corresponding to the first and second row commands are transferred through the first channel, and the bank addresses and the column addresses corresponding to the first and second column commands are transferred through the second channel.

24. The method of claim 18, further comprising:
performing a first row operation to control voltages of word lines in the first bank when the first row command is transferred to the first bank; and
performing a first column operation to control voltages of bit lines in the first bank when the first column command is transferred to the first bank.

25. The method of claim 24, wherein when the first row operation is performed once, the first column operation is performed multiple times by changing a column address.

26. The method of claim 24, further comprising:
performing a second row operation to control voltages of word lines in the second bank when the second row command is transferred to the second bank; and
performing a second column operation to control voltages of bit lines in the second bank when the second column command is transferred to the second bank.

27. The method of claim 26, wherein when the second row operation is performed once, the second column operation is performed multiple times by changing a column address.

28. The method of claim 26, wherein the first column operation and the second row operation are performed simultaneously.

29. A method for operating a memory system comprising a memory device, the method comprising:
transferring a row command to a first bank of the memory device through a first channel;
transferring a column command to a second bank of the memory device through a second channel;
performing a row operation in the first bank in response to the row command; and
performing a column operation in the second bank in response to the column command,
wherein the row operation and the column operation are performed in the same clock cycle of the memory device.
